(19) United States
(12) Patent Application Publication
(10) Pub. No.: US 2022/0087008 A1
(43) Pub. Date: Mar. 17, 2022

(54) ELECTRONIC DEVICE

(71) Applicant: Japan Display Inc., Tokyo (JP)

(72) Inventor: Takumi SANO, Tokyo (JP)

(73) Assignee: Japan Display Inc., Tokyo (JP)

(21) Appl. No.: 17/447,818

(22) Filed: Sep. 16, 2021

(30) Foreign Application Priority Data
Sep. 16, 2020 (JP) 2020-155514

(51) Int. Cl. H05K 1/02; H05K 1/11; H05K 1/18; G06F 3/044

(52) U.S. Cl. CPC H05K 1/028; G06F 3/044; H05K 1/181; H05K 1/118

(57) ABSTRACT

According to one embodiment, an electronic device includes a first insulating substrate having elasticity and including a plurality of first island-shaped portions and a first strip-shaped portion formed into a meandering strip shape and connecting the first island portions arranged along a first direction, first sensor electrodes disposed on each of the first island-shaped portions and a first sensor wiring line disposed on the first strip-shaped portion, meandering along the first strip-shaped portion, and connected to the first sensor electrode.

### CROSS-REFERENCE TO RELATED APPLICATIONS

This application is based upon and claims the benefit of priority from Japanese Patent Application No. 2020-155514, filed Sep. 16, 2020, the entire contents of which are incorporated herein by reference.

### FIELD

Embodiments described herein relate generally to an electronic device.

### BACKGROUND

In recent years, the use of flexible substrates with flexibility and elasticity has been studied in various fields. In flexible substrates, it is necessary to take measures to prevent damage to the wiring, which can be caused by stress by bending and stretching. As such measures, proposals have been made, for example, that the base material supporting the wiring should be formed into a honeycomb shape, or that wiring should be formed into a meandering shape.

### BRIEF DESCRIPTION OF THE DRAWINGS

FIG. 1 is a exploded perspective view schematically showing an electronic device 1 according to an embodiment.

FIG. 2 is a partially enlarged exploded perspective view showing a first substrate SUB1 and a second substrate SUB2 shown in FIG. 1.

FIG. 3 is a schematic cross-sectional view of the electronic device 1 including island-shaped portions I1 and I2.

FIG. 4 is a schematic cross-sectional view of the electronic device 1 including strip-shaped portions BX1 and BX2 shown in FIG. 3.

FIG. 5 is a schematic cross-sectional view of the electronic device 1 including strip-shaped portions BY1 and BY2 shown in FIG. 3.

FIG. 6 is a schematic cross-sectional view of the electronic device 1 shown in FIG. 2 in a state where a tensile force F parallel to the first direction X is applied.

FIG. 7 is an exploded perspective diagram showing another configuration example of the first substrate SUB1 and the second substrate SUB2 shown in FIG. 1.

FIG. 8 is a schematic cross-sectional view of the electronic device 1 including a strip-shaped portion BX1 shown in FIG. 7.

FIG. 9 is a schematic cross-sectional view of the electronic device 1 including the strip-shaped portion BY2 shown in FIG. 7.

FIG. 10 is a schematic plan view of the first substrate SUB1.

FIG. 11 is an enlarged plan view of a portion of the first substrate SUB1 shown in FIG. 10.

FIG. 12 is a diagram illustrating a drive circuit PC that drives an electric element E1.

FIG. 13 is a schematic cross-sectional view of the electronic device 1 including island-shaped portions I1 and I2 shown in FIG. 11.

FIG. 14 is a plan view showing another configuration example of the first substrate SUB1 shown in FIG. 10.

FIG. 15 is a schematic cross-sectional view of the electronic device 1 including island-shaped portions I1 and I2 shown in FIG. 14.

FIG. 16 is a plan view showing another configuration example of the first substrate SUB1 that constitutes the electronic device 1.

FIG. 17 is a plan view showing still another configuration example of the first substrate SUB1 that constitutes the electronic device 1.

### DETAILED DESCRIPTION

In general, according to one embodiment, an electronic device comprises a first insulating substrate having elasticity and including a plurality of first island-shaped portions and a first strip-shaped portion formed into a meandering strip shape and connecting the first island portions arranged along a first direction, first sensor electrodes disposed on each of the first island-shaped portions and a first sensor wiring line disposed on the first strip-shaped portion, meandering along the first strip-shaped portion, and connected to the first sensor electrode.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same elements as those described in connection with preceding drawings are denoted by like reference numerals, and a detailed description thereof is omitted unless otherwise necessary.

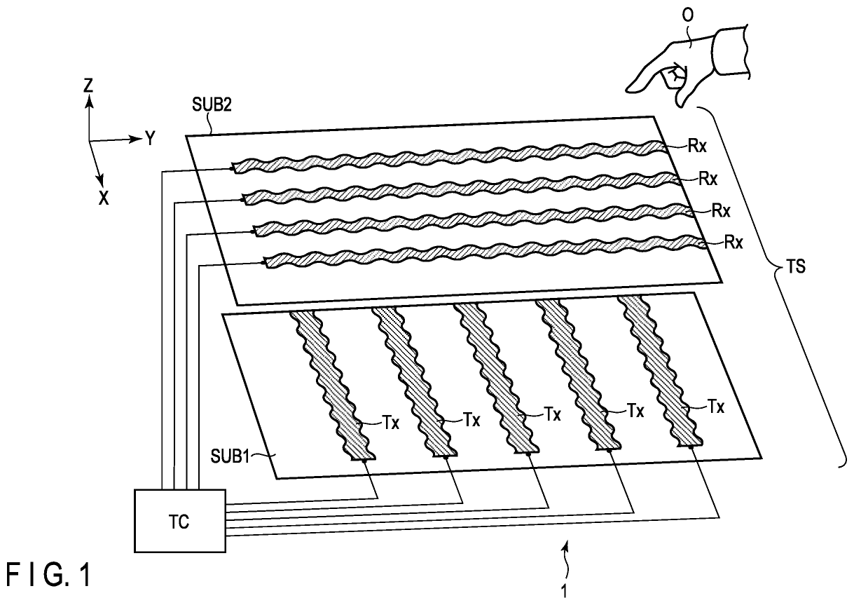

FIG. 1 is a schematic exploded perspective view of an electronic device 1 according to the present embodiment. In the embodiment, a first direction X, a second direction Y and a third direction Z are defined as shown in the figure. The first direction X, the second direction Y and the third direction Z are orthogonal to each other, but may intersect at an angle other than ninety degrees. The first direction X and the second direction Y correspond to directions parallel to a main surface of the electronic device 1, for example, and the third direction Z corresponds to a thickness direction of the electronic device 1.

The electronic device 1 described in this embodiment comprises a touch sensor TS capable of touch sensing. Touch sensing in this specification is not limited to detecting the presence or absence of an object (such as a user's finger) O in contact with the electronic device 1, but can also include detecting the presence or absence of an object O approaching the electronic device 1.

The electronic device 1 comprises a first substrate SUB1 and a second substrate SUB2. The second substrate SUB2 opposes the first substrate SUB1 along the third direction Z. The first substrate SUB1 comprises a plurality of drive electrodes Tx. The drive electrodes Tx each extend in a meandering manner along the first direction X and are arranged to be spaced apart from each other along the second direction Y. The second substrate SUB2 comprises a plurality of detection electrodes Rx. The detection electrodes Rx each extend in a meandering manner along the second direction Y and are arranged to be spaced apart from each other along the first direction X.

In plan view, the detection electrodes Rx intersect the driving electrodes Tx. That is, parts of the detection electrodes Rx oppose respective parts of the driving electrodes Tx along the third direction Z. The driving electrodes Tx and detecting electrodes Rx can respectively constitute mutual-capacitive type touch sensors TS. Note that the driving electrodes Tx can respectively constitute self-capacitive type touch sensors TS, and so can the detecting electrodes Rx.

Touch controllers TC, each controlling the touch sensing of the respective touch sensor TS, is built in, for example, an IC chip. The driving electrodes Tx and the sensing electrodes Rx are electrically connected to the touch controller TC.

The touch controller TC drives the drive electrodes Tx and reads sensor signals from the detection electrodes Rx. Based on the sensor signals, the touch controller TC or an external host detects the presence or absence of an object O approaching the electronic device 1, the presence or absence of an object O that has come into contact with the electronic device 1, the position coordinates of the object O that has come into contact, and the like.

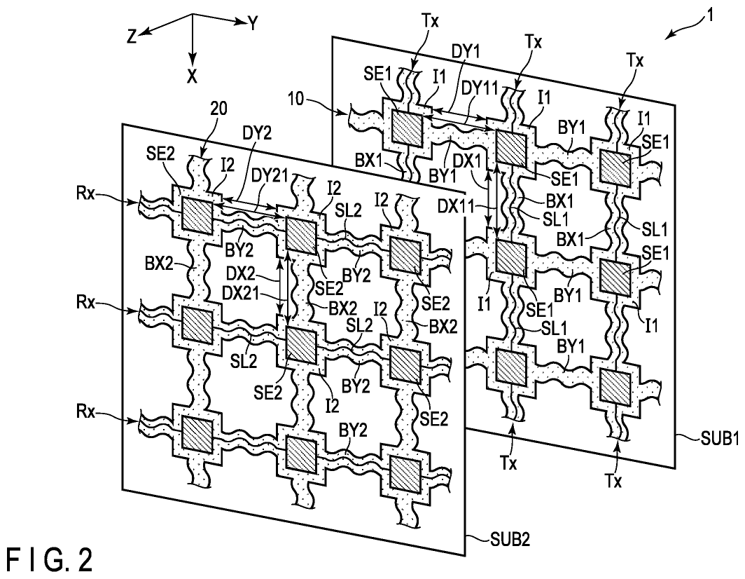

FIG. 2 is a partially enlarged exploded perspective view of the first substrate SUB1 and the second substrate SUB2 shown in FIG. 1. Each of the first substrate SUB1 and the second substrate SUB2 is a flexible substrate configured to be flexible and elastic as a whole.

The first substrate SUB1 comprises an elastic insulating substrate 10 and the second substrate SUB2 comprises an elastic insulating substrate 20. The term “elastic” refers to the property of being able to expand and contract, more specifically, the property of being able to expand from the normal, non-elongated state and to restore when released from this elongated state. The non-elongated state is the state when tensile stress is not applied.

The insulating base material 10 and the insulating base material 20 are formed into a mesh shape, for example. The insulating base material 10 and the insulating base material 20 will now be described in more detail.

The insulating base material 10 includes a plurality of strip-shaped portions BX1 formed substantially along the first direction X, a plurality of strip-shaped portions BY1 formed substantially along the second direction Y, and a plurality of island-shaped portions I1.

The strip-shaped portions BX1 are arranged to be spaced apart from each other along the second direction Y, and the strip-shaped portions BY1 are arranged to be spaced apart from each other along the first direction X. Each of the strip-shaped portions BX1 and BY1 is elastic. For example, the strip-shaped portions BX1 are each formed into a strip extending in a meandering manner along the first direction X, and the strip-shaped portions BY1 are each formed into a strip extending in a meandering manner along the second direction Y.

The island-shaped portions I1 each correspond to an intersection of each strip-shaped portion BX1 and each respective strip-shaped portion BY1. The island-shaped portions I1 are arranged in a matrix along the first direction X and the second direction Y. Each adjacent pair of island-shaped portions I1 along the first direction X are connected by the respective strip-shaped portions BX1, and each adjacent pair of island-shaped portions I1 along the second direction Y are connected by the respective strip-shaped portions BY1.

The insulating base material 20 is also formed in a similar manner to that of the insulating base material 10, and comprises a plurality of strip-shaped portions BX2 formed substantially along the first direction X, a plurality of strip-shaped portions BY2 formed substantially along the second direction Y, and a plurality of island-shaped portions I2.

The strip-shaped portions BX2 are arranged to be spaced apart from each other along the second direction Y, and the strip-shaped portions BY2 are arranged to be spaced apart from each other along the first direction X. Each of the strip sections BX2 and BY2 is elastic. For example, the strip-shaped portions BX2 are each formed as a strip extending in a meandering manner along the first direction X, and the strip-shaped portions BY2 are each formed as a strip extending in a meandering manner along the second direction Y.

The island-shaped portions I2 each corresponds to an intersection between each strip-shaped portion BX2 and each respective strip-shaped portion BY2. The island-shaped portions I2 are arranged in a matrix along the first direction X and the second direction Y. Each adjacent pair of island-shaped portions I2 along the first direction X are connected by the respective strip-shaped portions BX2, and each adjacent pair of island-shaped portions I2 along the second direction Y are connected by the strip-shaped portions BY2.

The island-shaped portions I1 and I2 may be quadrangulars such as squares, rectangles or rhombuses, or other polygons, or other shapes such as circles or ovals. Each of the strip-shaped portions BX1, BX2, BY1, and BY2 may be connected to a corner of the island-shaped portion of the respective polygonal or to an edge of the island-shaped portion.

In the unstretched state, the length of the strip-shaped portions BX1 along the first direction X is equivalent to the length of the strip-shaped portions BX2 along the first direction X. In other words, a distance DX1 between each adjacent pair of island-shaped portions I1 along the first direction X is equivalent to a distance DX2 between each adjacent pair of island-shaped portions I2 along the first direction X. Further, the length of the strip-shaped portions BY1 along the second direction Y is equivalent to the length of the strip-shaped portions BY2 along the second direction Y. That is, a distance DY1 between each adjacent pair of island-shaped portions I1 along the second direction Y is equivalent to a distance DY2 between each adjacent pair of island-shaped portions I2 along the second direction Y. Further, in the third direction Z, the strip-shaped portions BX2 overlap the strip-shaped portions BX1, respectively, the strip-shaped portions BY2 overlap the strip-shaped portions BY1, respectively, and the island-shaped portions I2 overlap the island-shaped portion I1, respectively.

In the first substrate SUB1, the drive electrodes Tx are arranged over respective strip-shaped portions BX1 and respective island-shaped portions I1. The drive electrodes Tx each comprises a plurality of sensor electrodes SE1 and a plurality of sensor wiring lines SL1.

Each of the sensor electrodes SE1 is disposed on the respective island-shaped portion I1. Each of the sensor wiring lines SL1 is arranged on the respective strip-shaped portion BXl so as to meander along the strip-shaped portion BX1. That is, the sensor wiring lines SL1 each extend in a meandering manner along the first direction X. The sensor electrodes SE1 arranged to be adjacent to each other along the first direction X are electrically connected by the sensor wiring lines SL1. For example, each sensor electrode SE1 and each respective sensor wiring line SL1 are formed to be integrated with each other from the same material, but the sensor electrodes SE1 may be formed of a material different from that of the sensor wiring lines SL1.

Neither the sensor electrodes SE1 nor the sensor wiring lines SL1 are arranged on the strip-shaped portions BY1, respectively. Note that, one drive electrode Tx to be independently controlled may be formed into a mesh-like pattern, in which case, a wiring line which connects each adjacent pair of sensor electrodes SE1 along the second direction Y may be arranged in the respective strip-shaped portion BY1.

In the second substrate SUB2, the detection electrodes Rx are arranged over respective strip-shaped portions BY2 and respective island-shaped portions I2. The detection electrodes Rx each comprises a plurality of sensor electrodes SE2 and a plurality of sensor wiring lines SL2.

Each of the sensor electrodes SE2 is disposed on the respective island-shaped portion I2. Each of the sensor wiring lines SL2 is arranged in the strip-shaped portion BY2 so as to meander along the respective strip-shaped portion BY2. In other words, the sensor wiring lines SL2 each extend in a meandering manner along the second direction Y. Each adjacent pair of sensor electrodes SE2 along the second direction Y are electrically connected to each other by the respective sensor wiring line SL2. The sensor electrodes SE2 and the sensor wiring lines SL2 may be formed to be integrated each other respectively from the same material, or the sensor electrodes SE2 may be formed of a material different from that of the sensor wiring lines SL2.

Neither the sensor electrodes SE2 nor the sensor wiring lines SL2 are arranged in the strip-shaped portion BX2. Note that one detection electrode Rx to be independently controlled may be formed into a reticular pattern, and in which case, a wiring line for connecting adjacent sensor electrodes SE2 along the first direction X may be arranged on the respective strip-shaped portion BX2.

In the non-extended state, a distance DX11 between each adjacent pair of sensor electrodes SE1 along the first direction X is equal to a distance DX21 between each adjacent pair of sensor electrodes SE2 along the first direction X. Further, a distance DY11 between each adjacent pair of sensor electrodes SE1 along the second direction Y is equal to a distance DY21 between each adjacent pair of sensor electrodes SE2 along the second direction Y. Moreover, along the third direction Z, the sensor electrodes SE2 overlap the sensor electrodes SE1, respectively.

As described above, each of the insulating base material 10 and the insulating base material 20 comprises a plurality of island-shaped portions and a plurality of strip-shaped portions connecting these island-shaped portions, and this structure makes it possible to expand and contract along the X-Y plane containing the first direction X and the second direction Y. That is, when tensile or compressive stress in a specific direction is applied to the insulating substrate 10 and the insulating substrate 20, the strip-shaped portions expand and contract according to the tensile or compressive stress. Further, the sensor wiring lines disposed on the strip-shaped portions similarly expand and contract. Thus, it is possible to provide an electronic device 1 that can be deformed into a shape according to tensile or compressive stress.

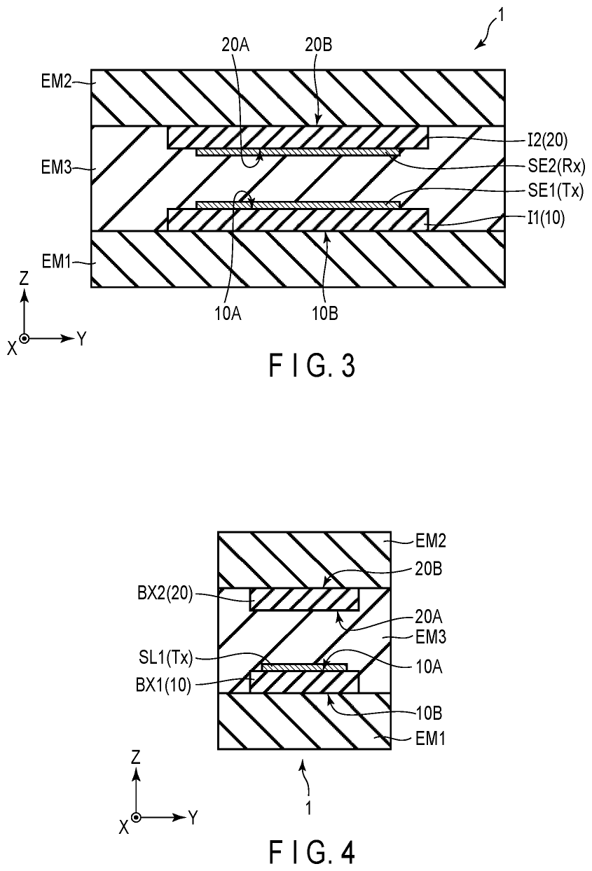

FIG. 3 is a schematic cross-sectional view of the electronic device 1 including the island-shaped portions I1 and I2. The insulating base material 10 comprises a main surface 10A and a main surface 10B on the opposite side to the main surface 10A. The sensor electrodes SE1 are each disposed on the main surface 10A of each respective island-shaped portion I1. Some other insulating film may be interposed between each sensor electrode SE1 and each respective island-shaped portion I1. The main surface 10B is in contact with the respective elastic member EM1.

The insulating base material 20 comprises a main surface 20A and a main surface 20B on the opposite side to the main surface 20A. The sensor electrodes SE2 are each disposed on the main surface 20A of each respective island-shaped portion I2. Some other insulating film may be interposed between each sensor electrode SE2 and each respective island-shaped portion I2. Along the third direction Z, each island-shaped portion I2 is located directly above each respective island-shaped portion I1, and each sensor electrode SE2 is located directly above each respective sensor electrode SE1. The main surface 20B is in contact with the elastic member EM2.

The insulating base material 10 and insulating base material 20 are formed of polyimide, for example, but may be formed using some other resin material. The sensor electrodes SE1 and SE2 are formed, for example, of a metal material, but may also be formed, for example, by a transparent conductive material such as indium tin oxide (ITO).

An elastic member EM3 is disposed between an elastic member EM1 and an elastic member EM2. In other words, the insulating base material 10 is located between the elastic member EM1 and the elastic member EM3, and the insulating base material 20 is located between the elastic member EM2 and the elastic member EM3. The elastic member EM3 covers the island-shaped portions I1, the sensor electrodes SE1, the island-shaped portions I2, and the sensor electrodes SE2. Some other insulating film may be provided between each sensor electrode SE1 and the elastic member EM3, and between each sensor electrode SE2 and the elastic member EM3.

The elastic member EM1, the elastic member EM2 and the elastic member EM3 are formed of an elastic transparent material. The elastic moduli (Young's moduli) of the elastic members EM1, EM2 and EM3 are equivalent to each other. For example, the elastic members EM1 and EM3 are formed of a resin material that has a modulus of elasticity lower than that of the insulating base material 10. The elastic members EM2 and EM3 are formed, for example, of a resin material that has a modulus of elasticity lower than that of the insulating base material 20. For example, the elastic member EM1, the elastic member EM2 and the elastic member EM3 are formed of the same material.

FIG. 4 is a schematic cross-sectional view of the electronic device 1 including the strip-shaped sections BX1 and BX2 shown in FIG. 3. The sensor wiring lines SL1 are each located on the main surface 10A of the respective strip-shaped portion BX1 and are covered by the elastic member EM3. Note that some other insulating film may be interposed between each sensor wiring line SL1 and each respective strip-shaped portion BX1, and between each sensor wiring line SL1 and the elastic member EM3. The main surface 10B is in contact with the elastic member EM1.

In the strip-shaped portions BX2, the main surface 20A is in contact with the elastic member EM3 and the main surface 20B is in contact with the elastic member EM2.

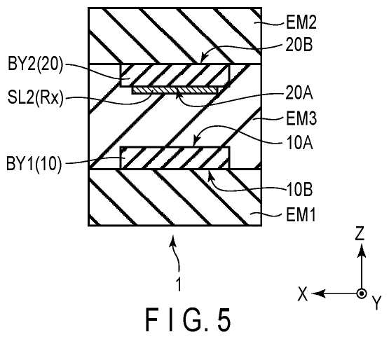

FIG. 5 is a schematic cross-sectional view of the electronic device 1 including the strip-shaped portions BY1 and BY2 shown in FIG. 3. The sensor wiring lines SL2 are each disposed on the main surface 20A of each respective strip-shaped portion BY2 and are covered by the elastic member EM3. Note that an insulating film may be interposed between each sensor wiring line SL2 and each respective strip-shaped portion BY2, and between each sensor wiring line SL2 and the elastic member EM3. The main surface 20B is in contact with the elastic member EM2.

In the strip-shaped portions BY1, the main surface 10A is in contact with the elastic member EM3 and the main surface 10B is in contact with the elastic member EM1.

In the area where the island-shaped portions I1, the strip-shaped parts BX1 and BY1 of the insulating base material 10 are not present, the elastic member EM3 is in contact with the elastic member EM1. In the area where the island-shaped portion I2, the strip-shaped portion BX2 and BY2 of the insulating substrate 20 are not present, the elastic member EM3 is in contact with the elastic member EM2.

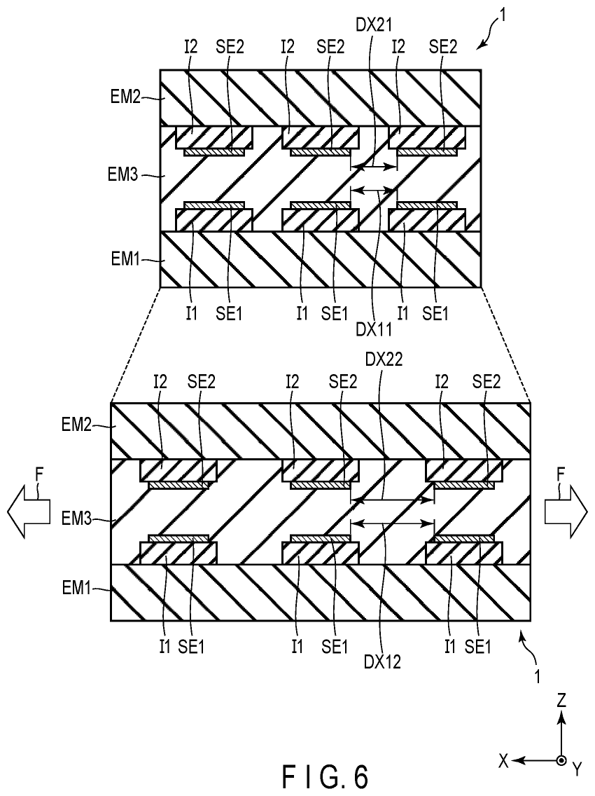

FIG. 6 is a schematic cross-sectional view showing a state of the electronic device 1 shown in FIG. 2, when a tensile force F parallel to the first direction X acts. In the state before the tensile force F is applied, the sensor electrodes SE2 overlap the sensor electrodes SE1 along the third direction Z, respectively. As described above, in the non-expanded state, the sensor electrodes SE1 are arranged to be spaced apart from each other by a distance DX11 along the first direction X, and the sensor electrodes SE2 are arranged to be spaced apart from each other by a distance DX21 (DX11=DX21) along the first direction X.

When the tensile force F acts, the entire electronic device 1 is stretched in the first direction X. Thus, the distance between each adjacent pair of sensor electrodes SE1 and the distance between each adjacent pair of sensor electrodes SE2 widen. In other words, the distance DX12 between each adjacent pair of sensor electrode SE1 is greater than the distance DX11 of each adjacent pair of sensor electrode SE1 before the tensile force F acts, whereas the distance DX22 of each adjacent pair of sensor electrodes SE2 is greater than the distance DX21 of each adjacent pair of sensor electrodes SE2 before the tensile force F acts. At this time, the distance DX22 is equal to the distance DX12. With this structure, even after the tensile force F acts, the sensor electrodes SE2 overlap the sensor electrodes SE1 in the third direction Z, respectively.

That is, the positional relationship between the sensor electrodes SE1 and SE2 does not substantially changes before and after the electronic device 1 is stretched. As a result, stable sensing can be carried out even when the electronic device 1 is stretched.

The above-described advantageous effects can also be obtained similarly when a force other than the tensile force F in the first direction X is applied to the electronic device 1. Such a force is assumed to be a compressive force in the first direction X, tensile force or compressive force in the second direction Y, and a tensile force F or compressive force in a direction intersecting the first direction X and the second direction Y, or the like. The electronic device 1 can as well be bent into an arbitrary shape.

As described above, according to this embodiment, it is possible to obtain an electronic device 1 that exhibits excellent flexibility and elasticity, and also capable of touch-sensing with stable and accurate sensibility.

In this specification, for example, the insulating base material 10 corresponds to the first insulating base material, the island-shaped portions I1 correspond to the first island-shaped portions, the strip-shaped portions BX1 correspond to the first strip-shaped portions, the strip-shaped portions BY1 correspond to the third strip-shaped portions, the sensor electrodes SE1 correspond to the first sensor electrode, the sensor wiring lines SL1 correspond to the first sensor wiring lines, the insulating base material 20 corresponds to the second insulating base material, the island-shaped portions I2 correspond to the second island-shaped portion, the strip-shaped portions BY2 correspond to the second strip-shaped portions, the strip-shaped portions BX2 correspond to the fourth strip-shaped portions, the sensor electrodes SE2 correspond to the second sensor electrodes, the sensor wiring lines SL2 correspond to the second sensor wiring lines, the elastic member EM1 corresponds to the first elastic member, the elastic member EM2 corresponds to the second elastic member, and the elastic member EM3 corresponds to the third elastic member.

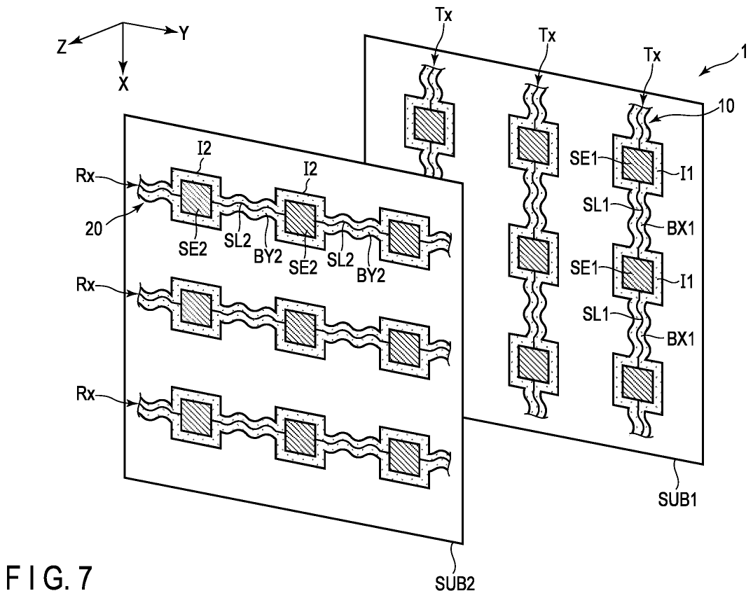

FIG. 7 is an exploded perspective view showing another configuration example of the first substrate SUB1 and the second substrate SUB2 shown in FIG. 1. The configuration example shown in FIG. 7 is different from that of FIG. 2 in that the insulating substrate 10 and the insulating substrate 20 are each formed in a stripe shape.

In the first substrate SUB1, the insulating substrate 10 comprises a plurality of strip-shaped portions BX1 formed substantially along the first direction X and a plurality of island-shaped portions I1, but does not include the strip-shaped portions BY1 shown in FIG. 2. The strip-shaped portions BX1 are elastic and are formed into a strip shape extending in a meandering manner along the first direction X. Each adjacent pair of island-shaped portions I1 along the first direction X are connected by the respective strip-shaped portion BX1, and each adjacent pair of island-shaped portions I1 along the second direction Y are not connected to each other.

The drive electrodes Tx each comprise a sensor electrode SE1 disposed on the respective island-shaped portion I1 and a sensor wiring lines SL1 disposed on the respective strip-shaped portion BX1. The sensor wiring lines SL1 are each formed to meander along the respective strip-shaped portion BX1 and connected to the respective sensor electrode SE1.

In the second substrate SUB2, the insulating substrate 20 comprises a plurality of strip-shaped portions BY2 formed substantially along the second direction Y and a plurality of island-shaped portions I2, but does not include the strip-shaped portion-shaped portions BX2 shown in FIG. 2. The strip-shaped portions BY2 are elastic and each formed into a strip-like shape extending in a meandering manner along the second direction Y. Each adjacent pair of island-shaped portions I2 along the second direction Y are connected to each other by the respective strip-shaped portion BY2, and each adjacent pair of island-shaped portions I2 along the first direction X are not connected to each other.

The detection electrodes Rx each comprise a sensor electrode SE2 disposed on the respective island-shaped portion I2 and a sensor wiring lines SL2 disposed on the respective strip-shaped portion BY2. The sensor wiring lines SL2 are each formed to meander along the respective strip-shaped portion BY2 and connected to the respective sensor electrode SE2.

In this configuration example, the island-shaped portions I1 and I2 overlap each other along the third direction Z, respectively and the sensor electrodes SE1 and SE2 overlap each other along the third direction Z, respectively. A cross-sectional structure of the electronic device 1 including the island-shaped portions I1 and I2 is shown in FIG. 3.

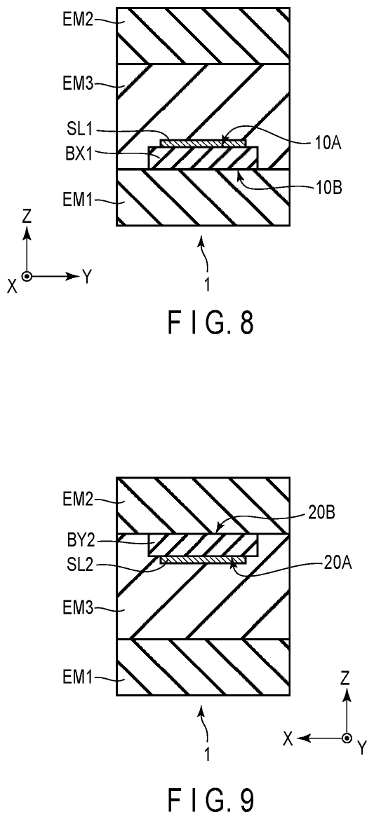

FIG. 8 is a schematic cross-sectional view of the electronic device 1 including the strip-shaped portions BX1 shown in FIG. 7. The sensor wiring lines SL1 are each disposed on the main surface 10A of the respective strip-shaped portion BX1 and covered by the elastic member EM3. The main surface 10B is in contact with the elastic member EM1. Along the third direction Z, no strip-shaped portions BX2 shown in FIG. 4 are present in the area opposing the sensor wiring lines SL1, and therefore the elastic members EM2 and EM3 are in contact with each other.

FIG. 9 is a schematic cross-sectional view of the electronic device 1 including the strip-shaped portions BY2 shown in FIG. 7. The sensor wiring lines SL2 are each disposed on the main surface 20A of the respective strip-shaped portion BY2 and covered by the respective elastic member EM3. The main surface 20B is in contact with the elastic member EM2. Along the third direction Z, no strip-shaped portions BY1 shown in FIG. 4 are present in the area opposing the sensor wiring lines SL2, and therefore the elastic member EM1 and the elastic member EM3 are in contact with each other.

Advantageous effects similar to those described above can be obtained in the configuration example described with reference to FIGS. 7 to 9.

Next, an electronic device 1 comprising electric elements E1 different from the touch sensors TS described above will be described. The following descriptions are directed to the case where the electric elements E1 are provided on the first substrate SUB1, but the electric element E1 may be provided on the second substrate SUB2, or on both the first substrate SUB1 and the second substrate SUB2. Further, the electronic device 1 may be applied to not only the case where a single type of electric elements E1 are provided in the electronic device 1, but also the case where multiple types of electric elements E1 are provided.

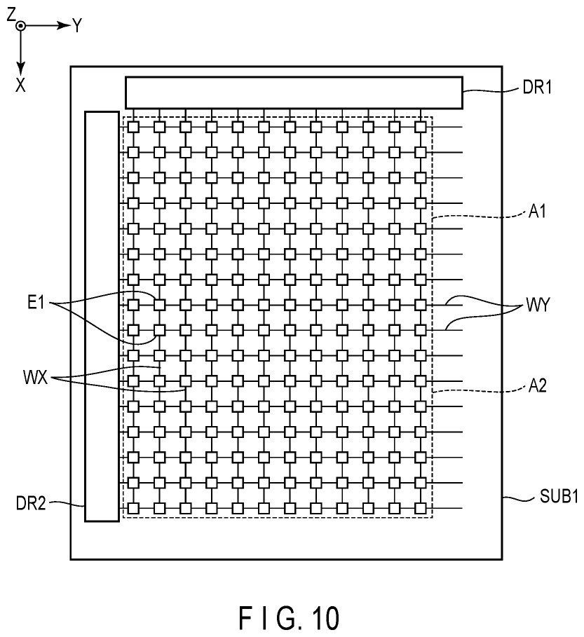

FIG. 10 is a schematic plan view of the first substrate SUB1. Note that in this figure, the touch sensors TS are omitted from the illustration.

The first substrate SUB1 comprises X wiring lines (first wiring lines) WX, Y wiring lines (second wiring lines) WY, electric elements E1 and the like.

The first driver DR1 and the second driver DR2 are disposed, for example, on the first substrate SUB1, but they may be disposed on some other circuit board.

The term “X wiring line WX” is a general term for wiring lines extending substantially along the first direction X. At least some of the X-wiring lines WX are electrically connected to the first driver DR1. The X-wiring lines WX are arranged along the second direction Y.

The term “Y wiring lines WY” is a general term for wiring lines extending substantially along the second direction Y, and at least some of the Y wiring lines WY are electrically connected to the second driver DR2. The Y-wiring lines WY are arranged along the first direction X. The X wiring lines WX and Y wiring lines WY include multiple types of wiring lines such as scanning lines, signal lines, power lines, and various control lines.

The electric elements E1 are arranged in a matrix along the first and second directions X and Y, and are electrically connected to the X-wiring lines WX and Y-wiring lines WY, respectively.

The electric elements E1 are, for example, sensors, semiconductor elements, or actuators. For example, as a sensor, an optical sensor that receives visible light or near-infrared light, a temperature sensor, or a pressure sensor can be applied. For example, as a semiconductor element, a light-emitting device, a light-receiving device, a diode, a transistor or the like can be applied. The electric elements E1 are not limited to those illustrated here, but some other element with various functions can be applied as well. The electric elements E1 may be capacitors, resistors or the like.

When the electric elements E1 are light-emitting devices, a flexible display having with flexibility and elasticity can be realized. The light-emitting devices each may be, for example, a micro-light emitting diode (LED) whose length of its longest side is 100 μm or less, or a mini-LED whose length of its longest side is greater than 100 μm and less than 300 μm, or an LED whose length of its longest side is 300 μm or more. The light-emitting devices each may be some other self-luminous device such as an organic electroluminescent device.

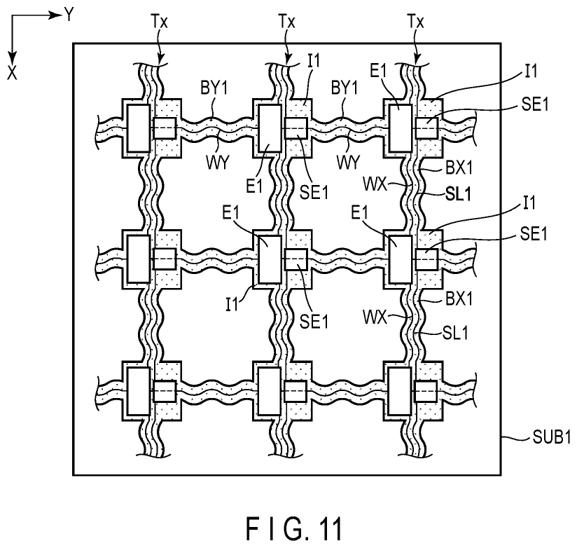

FIG. 11 is a partially enlarged plan view of the first substrate SUB1 shown in FIG. 10. Each electric element E1 and each respective sensor electrode SE1 are disposed side by side to be spaced apart from each other on the same island-shaped portion I1. Each X wiring line WX and each respective sensor wiring line SL1 are disposed on the same strip-shaped portion BX1 so as to meander along the strip-shaped portion BX1. Each Y wiring line WY is arranged on each respective strip-shaped portion BY1 so as to meander along the strip-shaped portion BY1. Each Y wiring line WY is disposed on each respective strip-shaped portion BY1 so as to meander along the strip-shaped portion BY1. The Y wiring lines WY intersect the drive electrodes Tx in the respective island-shaped portions I1. The electric elements E1 are electrically connected to the X wiring lines WX and Y wiring lines WY, respectively.

Note that for the second substrate opposing the first substrate SUB1, the configuration shown in FIG. 2 can be applied, and the explanation thereof will be omitted.

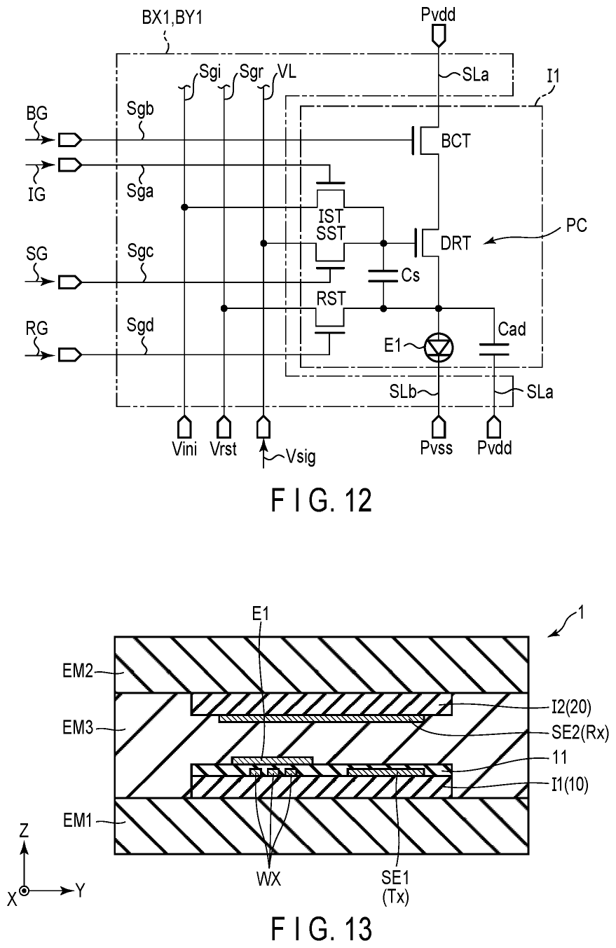

FIG. 12 is diagram illustrating a drive circuit PC that drives the respective electric element E1. The equivalent circuit shown in the figure is only an example and the embodiment is not limited to this example. Here, the case where the electric element E1 shown in FIG. 11 is a single light-emitting device (for example, a micro-LED) will be described. The electric elements E1 each may comprises a plurality of light-emitting devices.

The drive circuits PC each comprise a reset switch RST, a pixel switch SST, an initialization switch IST, an output switch BCT, a drive transistor DRT, an auxiliary capacitor Cs, and an auxiliary capacitor Cad. The reset switch RST, the pixel switch SST, the initialization switch IST, the output switch BCT, and the drive transistor DRT are each constituted by a thin film transistors (TFTs).

The drive transistor DRT and the output switch BCT are connected in series to the respective electric element E1 between a power line SLa and a power line SLb. One electrode (for example, an anode) of the electric element E1 is connected to the drive transistor DRT. The other electrode (for example, a cathode) of the electric element E1 is connected to the power line SLb. The auxiliary capacitor Cs is connected between the gate electrode and the source electrode of the drive transistor DRT. The auxiliary capacitor Cad is connected between the source electrode of the drive transistor DRT and the power line SLa.

The drain electrode of the output switch BCT is connected to the power line SLa. The source electrode of the output switch BCT is connected to the drain electrode of the drive transistor DRT. The gate electrode of the output switch BCT is connected to the scanning line Sgb. The source electrode of the pixel switch SST is connected to a video signal line VL. The drain electrode of the pixel switch SST is connected to the gate electrode of the drive transistor DRT. The gate electrode of the pixel switch SST is connected to the scanning line Sgc, which functions as a gate wiring line for controlling the writing of signals.

The source electrode of the initialization switch IST is connected to an initialization wiring line Sgi. The drain electrode of the initialization switch IST is connected to the gate electrode of the drive transistor DRT. The gate electrode of the initialization switch IST is connected to a scanning line Sga. The source electrode of the reset switch RST is connected to a reset wiring line Sgr. The gate electrode of the reset switch RST is connected to a scanning line Sgd, which functions as a gate wiring for reset control.

In the configuration described above, the drive circuit PC is controlled by control signals IG, BG, SG, and RG supplied to the scanning lines Sga, Sgb, Sgc, and Sgd, and the electric element E1 emits light at a luminance corresponding to the video signal Vsig of the video signal line VL.

For example, the electric element E1 and the drive circuit PC enclosed by a single-dotted chain line are disposed on the respective island-shaped portion I1 shown in FIG. 11. The scanning lines Sga, Sgb, Sgc, and Sgd, the video signal line VL, the power lines SLa, SLb, the reset wiring line Sgr, and the initialization wiring line Sgi enclosed by a double-dotted chain line each correspond to respective one of the X-wiring lines WX and the Y-wiring lines WY shown in FIG. 11, and are disposed on the respective strip-shaped portion BX1 or strip-shaped portion BY1 shown in FIG. 11.

FIG. 13 is a schematic cross-sectional view of the electronic device 1 including the island-shaped portions I1 and I2 shown in FIG. 11. The sensor electrode SE1, the X wiring lines WX, and the drive circuit PC and the like shown in FIG. 12 are disposed on the main surface 10A of the respective island-shaped portion I1 and covered by the insulating film 11. The insulating film 11 may be an organic insulating film or an inorganic insulating film. Each electric element E1 is disposed on the insulating film 11 and covered by the elastic member EM3.

In the example illustrated in FIG. 13, the sensor electrode SE2 is located directly above the sensor electrode SE1 and the electric element E1 along the third direction Z. Note that the sensor electrode SE2 may be displaced from the position directly above the electric element E1.

According to the configuration example described with reference to FIGS. 10 to 13, an electronic device 1 with the function of touch sensing and functions different from the touch sensing (for example, display, illumination, sensing, etc.), can be provided.

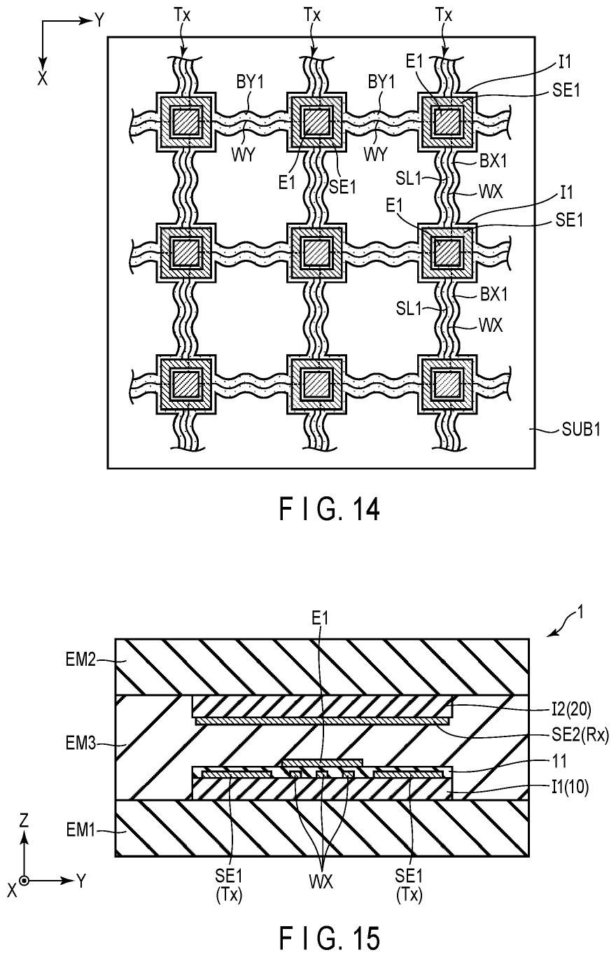

FIG. 14 is a plan view showing another configuration example of the first substrate SUB1 shown in FIG. 10. The configuration example shown in FIG. 14 is different from that of FIG. 11 in that the electric elements E1 are each disposed on an inner side surrounded by the respective sensor electrode SE1 in the same island-shaped portion I1. The X wiring lines WX and the sensor wiring lines SL1 are disposed on the strip-shaped portions BX1, respectively and the Y wiring lines WY are disposed on the strip-shaped portions BY1, respectively. The X wiring lines WX and Y wiring lines WY intersect the drive electrodes Tx in the respective island-shaped portions I1. The electric elements E1 are each electrically connected to the respective X wiring line WX and the respective Y wiring line WY.

Note that to the second substrate opposing the first substrate SUB1, the configuration shown in FIG. 2 can be applied, and therefore the explanation thereof will be omitted.

FIG. 15 is a schematic cross-sectional view of the electronic device 1 including the island-shaped portions I1 and I2 shown in FIG. 14. The X wiring lines WX and the drive circuit PC and the like shown in FIG. 12 are each disposed on an inner side of the sensor electrode SE1 on the main surface 10A of the respective island-shaped portion I1 and covered by the insulating film 11. The electric elements E1 are disposed on the insulating film 11 and covered by the elastic member EM3.

In this configuration example as well, advantageous effects similar to those described above can be obtained.

Next, the self-capacitive touch sensor TS will be described. Here, the case where the first substrate SUB1, which constitutes the electronic device 1, comprises a touch sensor TS will be described. In this case, the second substrate SUB2 may be omitted.

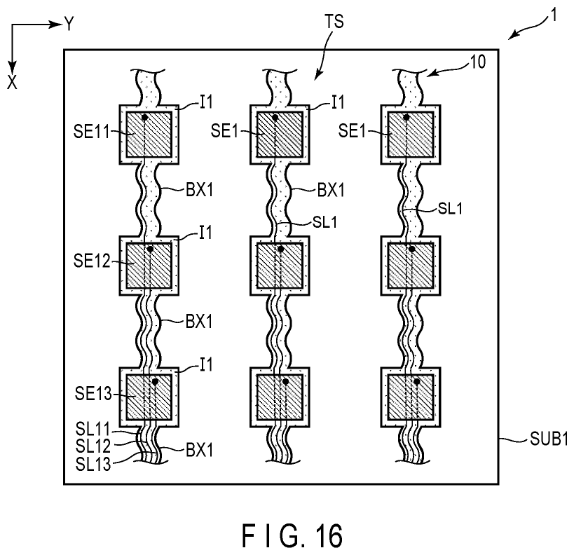

FIG. 16 is a plan view showing another configuration example of the first substrate SUB1 that constitutes the electronic device 1. The touch sensor TS comprises a plurality of sensor electrodes SE1 and a plurality of sensor wiring lines SL1. The sensor electrodes SE1 includes sensor electrodes SE11 to SE13 arranged to be spaced apart from each other with intervals along the first direction X. The sensor wiring lines SL1 include sensor wiring lines SL11 to SL13 arranged to be spaced apart from each other with intervals along the second direction Y.

Here, let us focus on the relationship between the sensor electrodes SE11 to SE13 and the sensor wiring lines SL11 to SL13. Each of the sensor wiring lines SL1 to SE13 is disposed over a plurality of island-shaped portions I1 and strip-shaped portions BX1 arranged along the first direction X.

The sensor wiring lines SL11 each overlap the sensor electrodes SE11 to SE13 in the respective island-shaped portions I1, and are electrically connected to the respective sensor electrode SE11.

The sensor wiring lines SL12 each overlap the sensor electrodes SE12 and SE13, and are electrically connected to the respective sensor electrode SE12. The sensor wiring lines SL12 do not overlap the sensor electrodes SE11.

The sensor wiring lines SL13 each overlap the respective sensor electrode SE13 and are electrically connected to the respective sensor electrodes SE13. The sensor wiring lines SL13 do not overlap the sensor electrodes SE11 and SE12.

Note that, in FIG. 16, a single sensor wiring line SL1 is connected to a single sensor electrode SE1, but multiple sensor wiring lines SL1 may be connected to one sensor electrode SE1, or multiple sensor electrodes SE1 may be connected to one sensor wiring LS1. In the configuration example shown in FIG. 16, the strip-shaped portions BY1 of the insulating base material 10 are omitted from the illustration, but the strip-shaped portions BY1 may be provided as in the case of the insulating base material 10 shown in FIG. 2.

Each of the sensor electrodes SE1 is connected to the touch controller TC shown in FIG. 1 via the respective sensor wiring line SL1. The touch controller TC drives each of the sensor electrodes SE1 and reads the sensor signals from the sensor electrodes SE1. Thus, the touch sensing can be carried out.

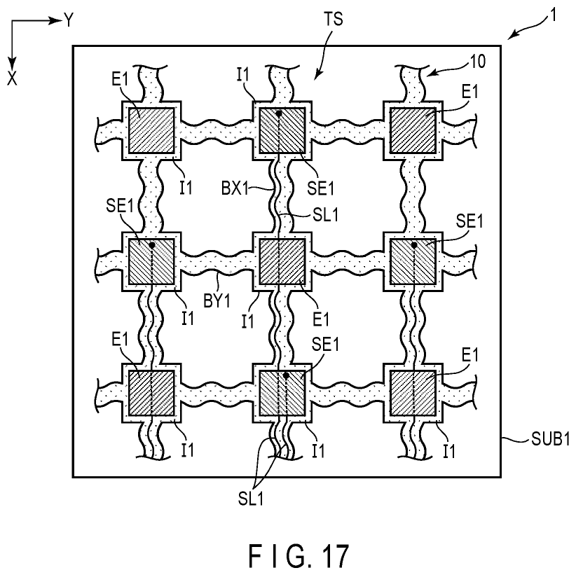

FIG. 17 is a plan view showing another configuration example of the first substrate SUB1 that constitutes the electronic device 1. The configuration example shown in FIG. 17 is different from that of FIG. 16 in that the first substrate SUB1 comprises electric elements E1 in addition to the self-capacitive touch sensor TS.

The electric elements E1 are disposed on island-shaped portions I1, respectively, which are different from the sensor electrodes SE1. As explained with reference to FIG. 11 and the like, the X wiring lines WX connected to the respective electric elements E1 are disposed on the strip-shaped portions BX1, respectively, and the Y wiring lines WY respectively connected to the electric elements E1 are disposed on the respective strip-shaped portions BY1. Note that the X wiring lines WX and Y wiring lines WY are omitted from the illustration.

The sensor wiring lines SL1 are disposed over a plurality of island-shaped portions I1 and strip-shaped portions BX1 and are electrically connected to the sensor electrodes SE1 of respective ones thereof. Further, the sensor wiring lines SL1 overlap the respective electric elements E1 in the island-shaped portions I1 in which the electric elements E1 are disposed, whereas overlap the respective sensor electrodes SE1 in the island-shaped portions I1 in which the sensor electrodes SE1 are disposed.

According to the configuration example, an electronic device 1 with the function of touch sensing and functions different from the touch sensing can be provided.

As explained above, according to the embodiments, an electronic device having flexibility and elasticity and also a function of touch sensing can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first insulating substrate having elasticity and including a plurality of first island-shaped portions and a first strip-shaped portion formed into a meandering strip shape and connecting the first island portions arranged along a first direction;
first sensor electrodes disposed on each of the first island-shaped portions; and
a first sensor wiring line disposed on the first strip-shaped portion, meandering along the first strip-shaped portion, and connected to the first sensor electrode.

2. The electronic device of claim 1, further comprising:
a second insulating substrate having elasticity and including a plurality of second island-shaped portions and a second strip-shaped portion formed into a meandering strip shape and connecting the second island-shaped portions arranged along a second direction different from the first direction;
second sensor electrodes disposed on each of the second island-shaped portions; and
a second sensor wiring line disposed on the second strip-shaped portion, meandering along the second strip-shaped portion and connected to the second sensor electrode,
wherein
the second sensor electrode overlaps the first sensor electrode.

3. The electronic device of claim 2, wherein
the first island-shaped portions in each of which the first sensor electrode is disposed and the second island-shaped portions in each of which the second sensor electrode is disposed are arranged in a matrix along the first and second directions, respectively,
an interval between each adjacent pair of first sensor electrodes along the first direction is substantially equal to an interval between each adjacent pair of second sensor electrodes along the first direction, and
an interval between each adjacent pair of first sensor electrodes along the second direction is substantially equal to an interval between each adjacent pair of second sensor electrodes along the second direction.

4. The electronic device of claim 2, further comprising:
a first elastic member, a second elastic member, and a third elastic member,
wherein
the first insulating substrate is located between the first elastic member and the second elastic member,
the second insulating substrate is located between the second elastic member and the third elastic member, and
moduli of elasticity of the first elastic member, the second elastic member, and the third elastic member are substantially equal to each other.

5. The electronic device of claim 1, further comprising an electric element disposed on each of the first island-shaped portions.

6. The electronic device of claim 5, wherein
the electric element and the first sensor electrode are disposed on a same first island-shaped portion, and are arranged to be spaced apart from each other.

7. The electronic device of claim 5, wherein
the electric element and the first sensor electrode are disposed on a same first island-shaped portion, and
the electric element is disposed on an inner side surrounded by the first sensor electrode.

8. The electronic device of claim 5, wherein
the electric element is disposed on each of the first island-shaped portions in a location different from that of the respective first sensor electrode.

9. The electronic device of claim 5, wherein
the electric element is a light-emitting device.
